(19) United States
(12) Patent Application Publication
(10) Pub. No.: US 2026/0150613 A1
(43) Pub. Date: May 28, 2026

(54) WET PROCESS SYSTEM AND PROCESS FOR USING THE SAME

(71) Applicant: TAIWAN SEMICONDUCTOR MANUFACTURING COMPANY LTD., HSINCHU (TW)

(72) Inventors: YUN-CHENG HSIEH, HSINCHU (TW); LING-SUNG WANG, TAINAN CITY (TW); HSU TUNG YEN, KAOHSIUNG CITY (TW); MI-CHUN HSU, TAINAN CITY (TW); JIA LING LIU, TAINAN CITY (TW)

(21) Appl. No.: 18/959,723

(22) Filed: Nov. 26, 2024

(51) Int. Cl. H01L 21/67

(52) U.S. Cl. CPC H10P 72/0436; H10P 72/0411; H10P 72/0418; H10P 72/0602

(57) ABSTRACT

A wet process system is provided. The wet process system includes a wafer holder, a thermal-emitting apparatus and a liquid provider. The wafer holder is configured to hold a wafer. The thermal-emitting apparatus is located above the wafer holder along a Y axis and is configure to emit thermal radiation to the wafer. The liquid provider is configured to provide treating liquid onto the wafer. The treating liquid provided on the wafer is heated by the thermal radiation emitted from the thermal-emitting apparatus.

### BACKGROUND

The semiconductor integrated circuit (IC) industry has experienced rapid growth. Technological advances in IC design and material have produced generations of ICs where each generation has smaller and more complex circuits than previous generations. In the course of IC evolution, functional density (i.e., the number of interconnected devices per chip area) has generally increased while geometry size (i.e., the smallest component (or line) that can be created using a fabrication process) has decreased.

This scaling down process generally provides benefits by increasing production efficiency and lowering associated costs. Such scaling down has also increased the complexity of IC processing and manufacturing. For these advances to be realized, similar developments in IC processing and manufacturing are needed. One area is the wiring, or interconnects, between the transistors and other devices. Although existing methods of fabricating IC devices have been generally adequate for their intended purposes, they have not been entirely satisfactory in all respects. For example, challenges rise to develop robust process for forming metal interconnection with low via resistance.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a block diagram of a wet process system in accordance with some embodiments of the present disclosure.

FIG. 2 is a configuration of a wet process system in accordance with some embodiments of the present disclosure.

FIG. 3 is a configuration of a wet process system in accordance with some another embodiments of the present disclosure.

FIG. 4A illustrates a perspective view of a thermal-emitting apparatus with a patterned screen used in a wet process system in accordance with some embodiments of the present disclosure.

FIG. 4B illustrates a bottom view of the thermal-emitting apparatus with the patterned screen used in the wet process system as shown in FIG. 4A in accordance with some embodiments of the present disclosure.

FIG. 5A illustrates a perspective view of a thermal-emitting apparatus with a detachable patterned screen used in a wet process system in accordance with some another embodiments of the present disclosure.

FIG. 5B illustrates a bottom view of the detachable patterned screen of the thermal-emitting apparatus used in the wet process system shown in FIG. 5A in accordance with some another embodiments of the present disclosure.

FIG. 6 is an exploded view of a holder with a substrate in a wet process system in accordance with some another embodiments of the present disclosure.

FIG. 7 illustrates a top view of the substrate as shown in FIG. 6 in accordance with some another embodiments of the present disclosure.

FIG. 8 is a flowchart of an exemplary process for cleaning a semiconductor device using a wet process system in accordance with some embodiments of the present disclosure.

FIGS. 9A to 9C illustrate an exemplary process for cleaning a semiconductor structure using a wet process system in accordance with some embodiments of the present disclosure, in which FIG. 9A shows a wafer with trench portions before being cleaned by a wet process system in accordance with some embodiments of the present disclosure; FIG. 9B shows the wafer with the trench portions shown in FIG. 9A being cleaned by the wet process system; and FIG. 9C shows the wafer with the trench portions filled with cleaning liquid through the wet process system.

FIG. 10 is a flowchart of an exemplary process for etching a semiconductor device using a wet process system in accordance with some embodiments of the present disclosure.

FIGS. 11A to 11C illustrate an exemplary process for etching a semiconductor structure using a wet process system in accordance with some embodiments of the present disclosure, in which FIG. 11A shows a wafer with semiconductor structures before being etched by a wet process system in accordance with some embodiments of the present disclosure; FIG. 11B shows the wafer with semiconductor structures shown in FIG. 11A being etched by a wet process system; and FIG. 11C shows the wafer with the semiconductor structures after being etched by the wet process system shown in FIG. 11B.

FIGS. 12A to 12C illustrate an exemplary process for etching a semiconductor structure using a wet process system in accordance with some embodiments of the present disclosure, in which FIG. 12A shows a wafer with semiconductor structures before being etched by a wet process system in accordance with some embodiments of the present disclosure; FIG. 12B shows the wafer with semiconductor structures shown in FIG. 12A being etched by a wet process system; and FIG. 12C shows the wafer with the semiconductor structures after being etched by the wet process system shown in FIG. 12B.

### DETAILED DESCRIPTION OF THE DISCLOSURE

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 100 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

When manufacturing a semiconductor device, a profile modification process may include a wet process, such as a wet etching or a wet cleaning, performed on trench portions or other gaps. However, etching/cleaning efficiency is challenging due to increased aspect ratio of trench portions or other gaps (that is, decreased process window). For example, an etching/cleaning solution is difficult to be filled in the trench portions or other gaps, the resulting semiconductor structures would not have performance as desired. Furthermore, removal efficiency would be more difficult when there is a need to partially etch/clean the trench portions or other gaps. It is desired to have improvements in the etching/cleaning of trench portions or other gaps.

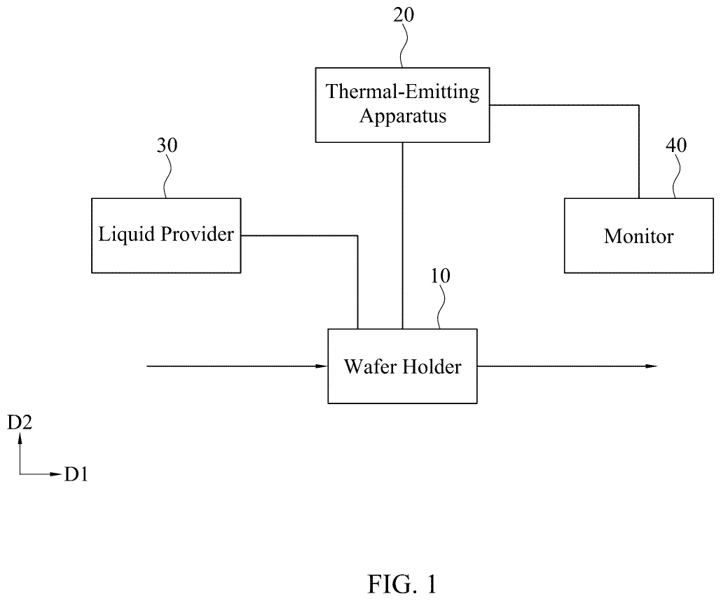

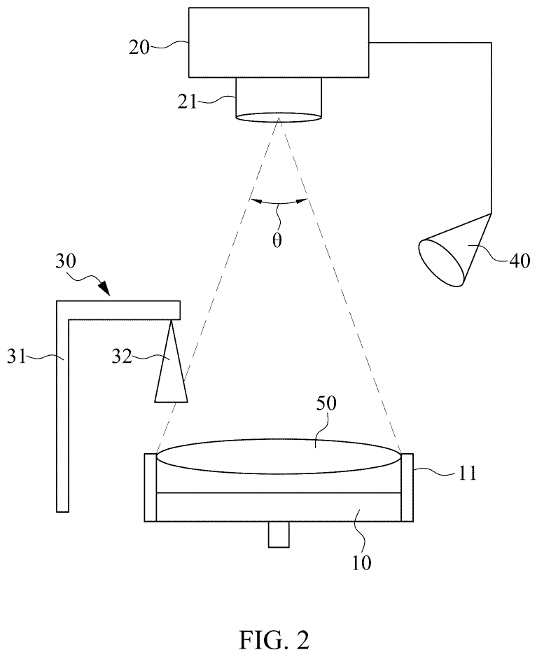

Referring to FIGS. 1 and 2, a wet process system is provided. In some embodiments, the wet process system in accordance with the present disclosure is used to treat a wafer 50 (for example, etching or cleaning semiconductors formed on the wafer 50) and comprises a wafer holder 10, a thermal-emitting apparatus 20, a liquid provider 30 providing liquid (or gel) onto the wafer 50, such as etching/cleaning liquid, and a monitor 40.

The wafer holder 10 can be coupled to a transfer mechanism (for example, a motorized robotic transfer arm) transferring the wafer 50 along a first direction D1 (i.e., along the X axis). In some embodiments, the wafer holder 10 fixes the wafer 50 and exposes a front surface and a back surface of the wafer 50 for inspection. In some embodiments, wafer holder 10 may include multiple support pins and/or multiple clamp pins 11 to hold the wafer 50 and prevent the wafer 50 from sliding during the wafer treating process. In some embodiments, an inner flow system (not shown) can be operatively coupled to the wafer holder 10 and configured to introduce gas flow to wafer 50 during the wafer cleaning process to facilitate the removal of etching/cleaning liquid.

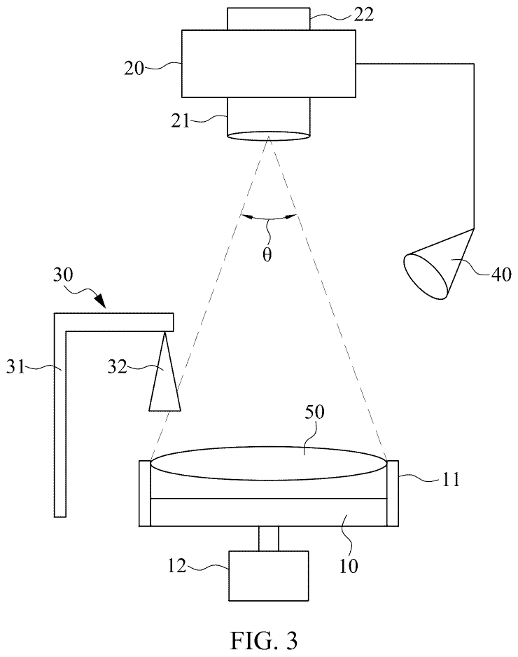

The wafer 50 may or may not be rotated while etching/cleaning liquid is supplied (or dispensed) on the wafer 50. In some embodiments, the wafer holder 10 itself may be rotatable. In some alternative embodiments, the wafer holder 10 may be further attached to a spin base 12 as shown in FIG. 3. In some embodiments, the wafer holder 10 can spin the wafer 50 via the spin base 12 at a predetermined spin speed during the wafer treating process. The spin speed may range from about 1 rpm to about 1,000 rpm. In some embodiments, the spin speed may range from about 5 rpm to about 800 rpm. In some embodiments, the spin speed may range from about 10 rpm to about 500 rpm.

As used herein, a front surface of the wafer 50 refers to a major surface on which semiconductor structures to be treated are formed. When the wafer 50 is held onto the wafer holder 10, the front surface faces upward (e.g., facing the thermal-emitting apparatus 20).

The thermal-emitting apparatus 20 is located above the wafer holder 10 along a second direction D2 (i.e., along the Y axis) perpendicular to the first direction D1. The thermal-emitting apparatus 20 comprises an emitter 21 emitting thermal radiation. For example, the emitter 21 may be a multi-bean laser projector or a single light source projector. In some embodiments, the emitter 21 may emit light with desired wavelength, intensity and the like. The wavelength of the light emitted from the emitter 21 may range from about 300 nm to about 3,000 nm. Thermal energy can be transferred by radiation, mostly in the infrared (IR) light and visible range. In some embodiments, the emitter 21 may emit infrared light or visible light. In some embodiments, a distance between the thermal-emitting apparatus 20 and the wafer holder 10 may range from about 1 cm to about 100 cm. In some embodiments, the distance between the thermal-emitting apparatus 20 and the wafer holder 10 may range from about 5 cm to about 80 cm. In some embodiments, the distance between the thermal-emitting apparatus 20 and the wafer holder 10 may range from about 10 cm to about 50 cm. In some embodiments, a field of view (FOV) θ from a center of the emitter 21 to an edge of the wafer 50 may range from about 15° to about 175°. In some embodiments, the field of view θ may range from about 30° to about 160°. In some embodiments, the field of view θ may range from about 45° to about 150°.

Power of light emitted from the emitter 21 may range from about 0.1 W to 2,000 W, so that the etching/cleaning liquid provided on the wafer 50 can be heated, so that the temperature of the etching/cleaning liquid can be raised about 0.1° C. to about 100° C. In some embodiments, the temperature of the etching/cleaning liquid can be raised about 0.5° C. to about 80° C. In some embodiments, the temperature of the etching/cleaning liquid can be raised about 1° C. to about 50° C. In some embodiments, the temperature of the etching/cleaning liquid can be raised about 1.5° C. to about 30° C.

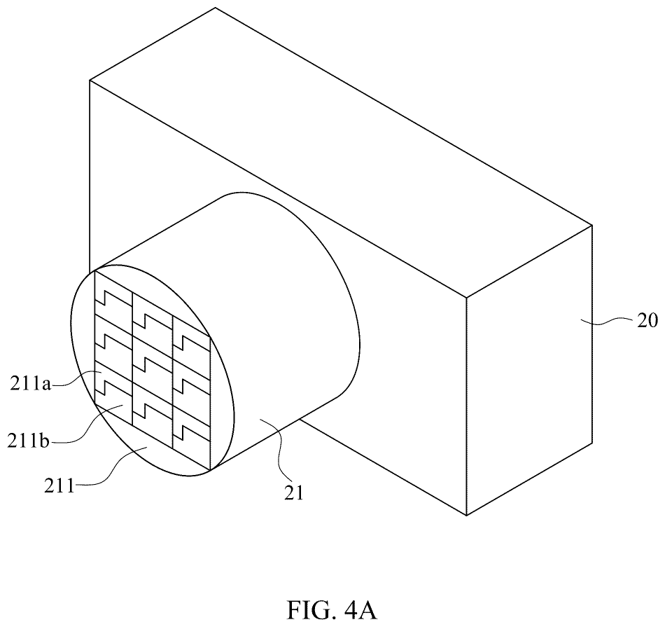

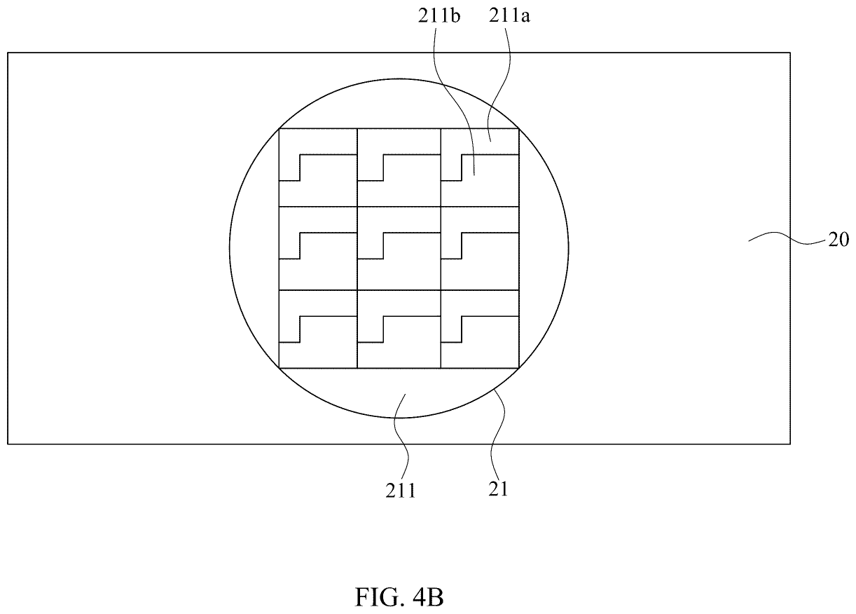

In some embodiments as shown in FIGS. 4A and 4B, the emitter 21 has a patterned screen 211 including emitting portions 211a and blocking portions 211b arranged with a predetermined pattern, corresponding to predetermined regions of the semiconductor structures to be etched/cleaned on the major surface of the wafer 50. The light can be emitted from the emitter 21 from the emitting portions 211a of the patterned screen 211 and can be blocked by the blocking portions 211b. Hence, the major surface of the wafer 50 can be partially heated through the light and thus can be partially etched/cleaned according to the predetermined pattern.

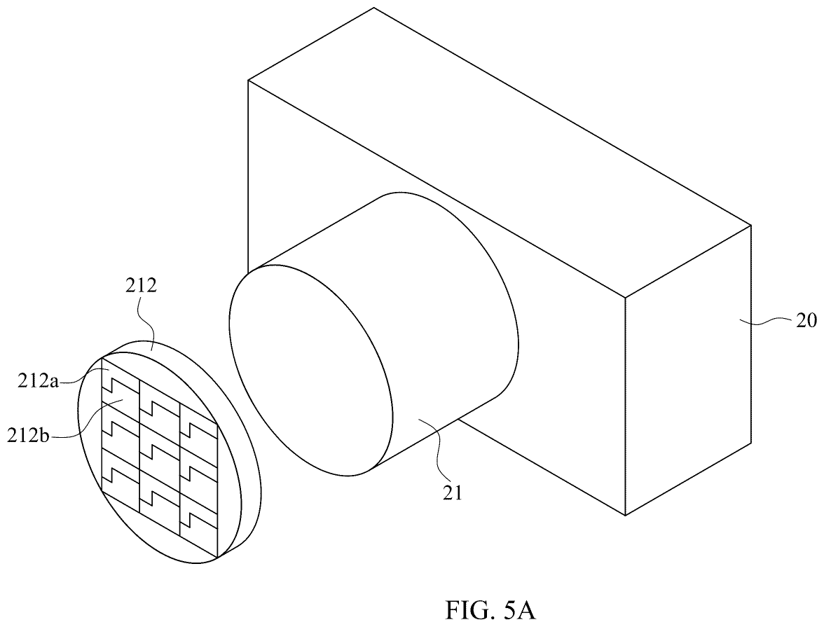

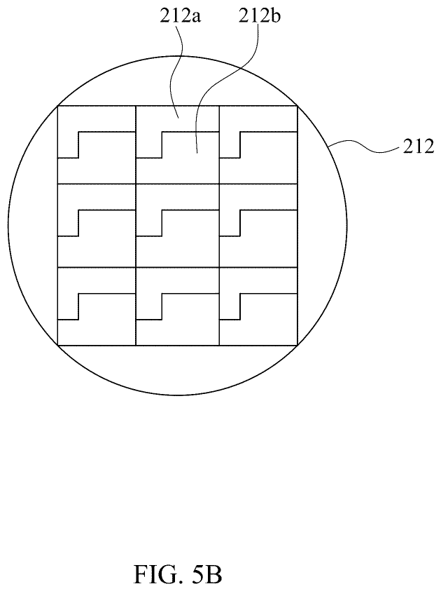

In some another embodiments as shown in FIGS. 5A and 5B, the emitter 21 has a detachable patterned screen 212 including emitting portions 212a and blocking portions 212b arranged with a predetermined pattern, corresponding to predetermined regions 51 of the semiconductor structures to be etched/cleaned on the major surface of the wafer 50. The light can be emitted from the emitter 21 from the emitting portions 212a of the patterned screen 212 and can be blocked by the blocking portions 212b. Hence, the major surface of the wafer 50 can be partially heated through the light and thus can be partially etched/cleaned according to the predetermined pattern. The detachable patterned screen 212 can be attached to the emitter 21 when treating the wafer 50. The detachable patterned screen 212 can be switched according to desired patterns. When treating wafers 50 including semiconductor structures with different required patterns, a suitable detachable patterned screen 212 with the required pattern can be switched as desired.

In some alternative embodiments, the emitter 21 may be a multi-beam laser projector, which may emit light with the predetermined pattern, corresponding to predetermined regions 51 of the semiconductor structures to be etched/cleaned on the major surface of the wafer 50. Hence, the major surface of the wafer 50 can be partially heated through the light emitted from the multi-beam laser projector and thus can be partially etched/cleaned according to the predetermined pattern.

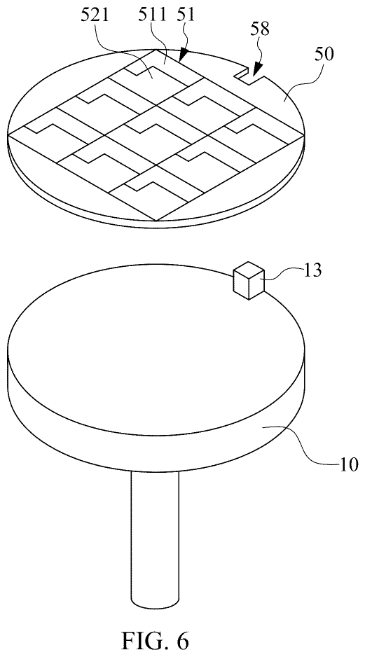

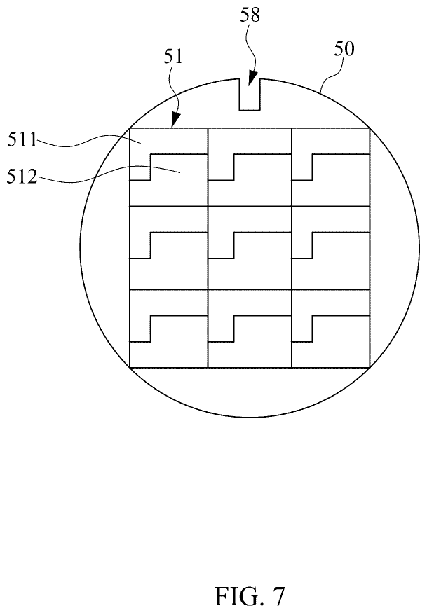

As shown in FIGS. 6 and 7, the wafer 50 with semiconductor structures can be heated by thermal energy emitted from the emitter 21 through the patterned screen 211 or the detachable patterned screen 212. The semiconductor structures on the major surface of the wafer 50 has predetermined regions 51 including treating areas 511 to be etched/cleaned and protecting areas 512, which are protected from the etch or clean operations. The treating areas 511 correspond to the emitting portions 211a/212a of the patterned screen 211/the detachable patterned screen 212, and the protecting areas 512 correspond to the blocking portions 211b/212b of the patterned screen 211/the detachable patterned screen 212. Therefore, the treating areas 511 of the wafer 50 can be heated by the thermal energy emitted from the emitter 21, so the etching/cleaning efficiency of the treating areas 511 is better than the protecting areas 512, which makes selective etching/cleaning possible.

In some embodiments, the emitter 21 itself may be rotatable. In some alternative embodiments, the emitter 21 may be further attached to a rotational chuck 22 as shown in FIG. 3. The emitter 21 may spin symphonically with spinning the wafer 50 held by the wafer holder 10 during the wafer treating process, so that emitting portions 211a/212a of the patterned screen 211/the detachable patterned screen 212 can follow the treating areas 511 when the wafer 50 is spinning. The wafer holder 10 spins the wafer 50 at a spin speed, which is substantially identical to a spin speed of the emitter 21 driven by the rotational chuck 22. The emitter 21 may spin at a spin speed ranging from about 1 rpm to about 1,000 rpm. In some embodiments, the spin speed may range from about 5 rpm to about 800 rpm. In some embodiments, the spin speed may range from about 10 rpm to about 500 rpm.

The liquid provider 30 can include a swing arm 31 and a nozzle 32. The swing arm 31 can move the nozzle 32 over the major surface of the wafer 50. The nozzle 32 is configured to supply a flow of (or dispense) the etching/cleaning liquid onto the major surface of the wafer 50. The nozzle 32 can be attached to the swing arm 31 and can be configured to supply a flow of (or dispense) the etching/cleaning liquid onto the major surface of the wafer 50. In some embodiments, the nozzle 32 can be a pressure nozzle configured to rinse the wafer 50. In some embodiments, the liquid provider 30 may be equipped with more than one nozzle 32 depending on demand. In some embodiments, the distance between the nozzle 32 and the wafer 50 can be adjusted or remain fixed for the duration of the wafer treating process. In some embodiments, the orientation of the nozzle 32 with respect to the major surface of the wafer 50 (e.g., the angle between the nozzle 32 with respect to the major surface of wafer 50) can also be adjusted or remain fixed, according to some embodiments. The nozzle 32 can be connected, via one or more chemical switch boxes (not shown), to external tanks (not shown) with chemicals. The chemical switch boxes can be chemical distribution systems, where valves and chemical distribution lines are housed and chemical solutions are pre-mixed prior to delivery to the nozzle 32. In some embodiments, while the etching/cleaning liquid is supplied (or dispensed) on the major surface of the wafer 50, the wafer 50 may or may not be rotated. At the same time, the emitter 21 may or may not spin.

The spinning of the wafer 50 helps the etching/cleaning liquid overcome surface tension, so the etching/cleaning liquid would easily flow into trench portions or other gaps even with high aspect ratio and thus etching/cleaning efficiency can be increased.

In some embodiments, a portion of an outer surface of the nozzle 32 can be covered with a conductive layer to reduce the risk of static electric charge that can occur at the nozzle 32 during the wafer treating process. In some embodiments, the nozzle 32 can be made of polychlorotrifluoroethylene (PCTFE) and/or polytetrafluoroethylen (PTFE), which have static electricity values (e.g., −4.58 kV for PCTFE) that can increase the risk of static electric charge during the operation of the nozzle 32. By coating a portion of the outer surface of the nozzle 32 with conductive layer, such as a conductive material with static electricity higher than about −4 kV (e.g., higher than about −4 kV, about −3.5 kV, about −3 kV, about −2.5 kV, about −2 kV, about −1.5 kV, or about −1 kV), the risk of static electric charge can be reduced. In some embodiments, conductive layer can include carbon nanotubes with a carbon doping of about between 0.025 weight (wt) % and about 0.1 wt % (e.g., between 0.025 wt % and 0.1 wt %, between 0.03 wt % and 0.09 wt %, between 0.04 wt % and 0.08 wt %, or between 0.05 wt % and 0.07 wt %). In some embodiments, an additional grounding unit, such as a grounding plate or a conductive wire connecting to an external ground level, can be coupled to the nozzle 32 to further reduce the risk of static electric charge. In some embodiments, the nozzle 32 can further include an ionizer configured to supply corona discharges to cleaning nozzle to reduce the static electric charge. Corona discharges can be electrical discharges generated by an ionization of a fluid, such as air, surrounding a conductor (e.g., conductive layer coated on the outer surface of the nozzle 32) that is electrically charged.

The etching/cleaning liquid may be water, aqueous solution, acid, alkaline, organic solvent (such as organic acid), and a mixture thereof. In some embodiments, an etching liquid may include deionized water, ammonium hydroxide (NH₄OH), hydrofluoric acid (HF), diluted HF, hydrogen peroxide (H₂O₂), sulfuric acid (H₂SO₄), tetramethylammonium hydroxide (TMAH), other suitable wet etching solution, or combinations thereof. For example, the wet etching solution can utilize an NH₄OH:H₂O₂ solution, an NH₄OH:H₂O₂:H₂O solution (known as an ammonia-peroxide mixture (APM)), or an H₂SO₄:H₂O₂ solution (known as a sulfuric peroxide mixture (SPM)). In some embodiments, the cleaning liquid can include, but is not limited to, hydrofluoric acid, hydrochloric acid, sulfuric acid, hydrogen peroxide, ammonium hydroxide, acetone, methanol, isopropyl alcohol, deionized water (DI water), or a combination thereof. In some embodiments, the cleaning liquid can be a solution including, but is not limited to, a hydrochloric acid/hydrogen peroxide/DI water (HPM) solution, a sulfuric acid/hydrogen peroxide/DI water (SPM) solution, a hydrochloric acid/ozone/DI water (HOM) solution, a sulfuric acid/ozone/DI water (SOM) solution, an ammonium hydroxide/ozone/DI water (AOM) solution, a hydrofluoric acid/DI water (DHF) solution, an ozone solution (ozone diluted in DI water), or a combination thereof. One or more of the etching/cleaning liquid can be supplied on the wafer successively and independently from one another at different stages of the wafer treating process. For example, an exemplary wafer treating process can include a DHF operation and an HPM operation with another cleaning operation in between. Depending on the specific etching/cleaning liquid used for treating wafer 50, the emitter 21 may heat the wafer 50 to a suitable temperature. For example, for isopropyl alcohol, the wafer 50 may be heated to a temperature ranging from about 190° C. to about 195° C. for about 30 seconds to boil the isopropyl alcohol. In some embodiments, the wafer 50 may be heated to a temperature ranging from about 75° C. to about 85° C. for about 10 minutes to boil the ammonium hydroxide/hydrogen peroxide/DI water (e.g., SCI clean). In some embodiments, the wafer 50 can be heated to a temperature ranging from about 75° C. to about 85° C. for about 10 minutes to boil the hydrochloric acid/hydrogen peroxide/DI water (e.g., SC₂ clean).

The choice of cleaning liquid can be determined by contaminants on the major surface of wafer 50. By way of example and not limitation, the HPM mixture is an acidic solution capable of removing metals from the major surface of the wafer 50. In some embodiments, the HPM can be a solution with high oxidation potential (e.g., higher than about 1.3 V) and low pH (e.g., below about 7). Consequently, metal contaminants on the major surface of the wafer 50 can be ionized and dissolved in the HPM solution during the wafer cleaning process.

In some embodiments, the etching/cleaning liquid may be provided onto the major surface of the wafer 50 to form a thin film with a thickness ranging from about 0.01 μm to about 3 mm. In some embodiments, a thickness of the etching/cleaning liquid onto the major surface of the wafer 50 may range from about 0.05 μm to about 2 mm. In some embodiments, a thickness of the etching/cleaning liquid onto the major surface of the wafer 50 may range from about 0.1 μm to about 1.5 mm. The temperature difference between the etching/cleaning liquid flowing out from the liquid provider 30 and the etching/cleaning liquid after being heated by thermal energy emitted from the emitter 21 may range from about 0.1° C. to about 100° C. In some embodiments, the temperature difference may range from about 0.5° C. to about 80° C. In some embodiments, the temperature difference may range from about 1° C. to about 50° C. In some embodiments, the temperature difference may range from about 1.5° C. to about 30° C.

During the wafer treating process, the etching/cleaning liquid can be provided from the nozzle 32 onto the major surface of the wafer 50, and the wafer 50 receives thermal energy emitted from the emitter 21 of the thermal-emitting apparatus 20, so that the etching/cleaning liquid provided on the wafer 50 can be heated to enhance the etching/cleaning efficiency. In some embodiments, as shown in FIGS. 6 and 7, the treating areas 511 of the semiconductor structures on the major surface of the wafer 50 can be heated by thermal energy emitted from the emitter 21 through the patterned screen 211/the detachable patterned screen 212, so that the etching/cleaning liquid on the treating areas 511 of the wafer 50 can be heated to enhance the etching/cleaning efficiency in the treating areas 511. Therefore, selective etching/cleaning can be achieved. The temperature of the etching/cleaning liquid on the treating areas 511 may have a higher temperature than that on the protecting areas 512 since the treating areas 511 receives thermal energy emitted from the emitter 21 of the thermal-emitting apparatus 20. The temperature difference between the etching/cleaning liquid on the protecting areas 512 and the etching/cleaning liquid on the protecting areas 512 may range from about 0.1° C. to about 100° C. In some embodiments, the temperature difference may range from about 0.5° C. to about 80° C. In some embodiments, the temperature difference may range from about 1° C. to about 50° C. In some embodiments, the temperature difference may range from about 1.5° C. to about 30° C.

The monitor 40 is used to monitor the progress of the wafer treating process and transmit collected data to other units, such as the wafer holder 10, the thermal-emitting apparatus 20 and/or the liquid provider 30. In some embodiments, the monitor 40 may comprise a real-time temperature sensor (such as an infrared (IR) thermometer, thermal camera and the like), which monitors temperature of the etching/cleaning liquid on the major surface of the wafer 50 and transmits the collected temperature data to the thermal-emitting apparatus 20, so that the thermal-emitting apparatus 20 can real-time adjust the power of the light emitted from the emitter 21. In some embodiments, the monitor 40 may comprise a speed sensor, which monitors the spin speed of the wafer 50 and transmits the collected speed data to the wafer holder 10 and/or the thermal-emitting apparatus 20, so that the rotation of the wafer holder 10 and/or the rotation of the patterned screen 211 of the emitter 21 can be real-time controlled to ensure that the emitter 21 can spin symphonically with spinning wafer 50 held by the wafer holder 10. In some embodiments, additional sensor(s) can be used to monitor attributes associated with other units in the wet process system, such as but not limited to, a level of residue/contamination retained on wafer 50, environmental pressure and/or humidity and so on to ensure safety and/or manufacturing quality.

In some embodiments, the wafer 50 and/or the wafer holder 10 may have alignment structures. For example, the wafer 50 may have an alignment notch 58 and the wafer holder 10 may have a positioning structure 13 corresponding to and fitting into the alignment notch 58 as shown in FIGS. 6 and 7, so that the position of the wafer 50 can be calibrated with an aid of the alignment notch 58 of the wafer 50 and the positioning structure 13 of the wafer holder 10. Therefore, when using the patterned screen 211/the detachable patterned screen 212, the emitting portions 211a, 212a can accurately correspond the treating area 511 on the wafer 50, and the blocking portions 211b can accurately correspond to the protecting areas 512 on the wafer 50. Other calibration (alignment) methods/devices can also be used to ensure the accurate position of the wafer 50 before being etching/cleaning.

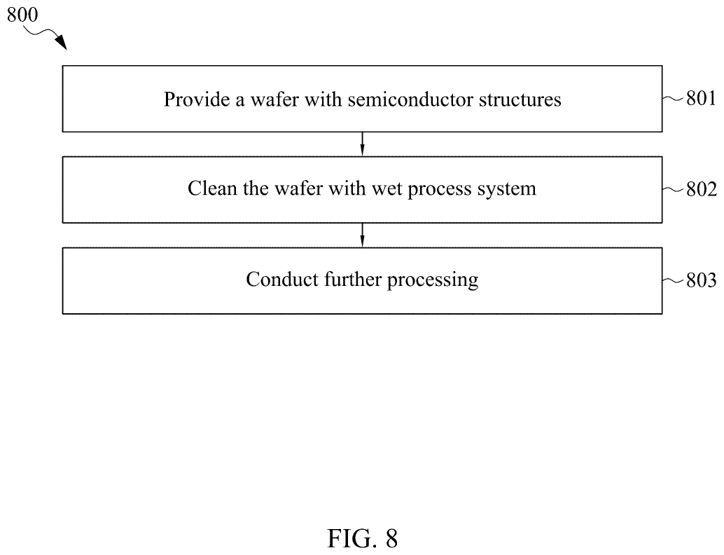

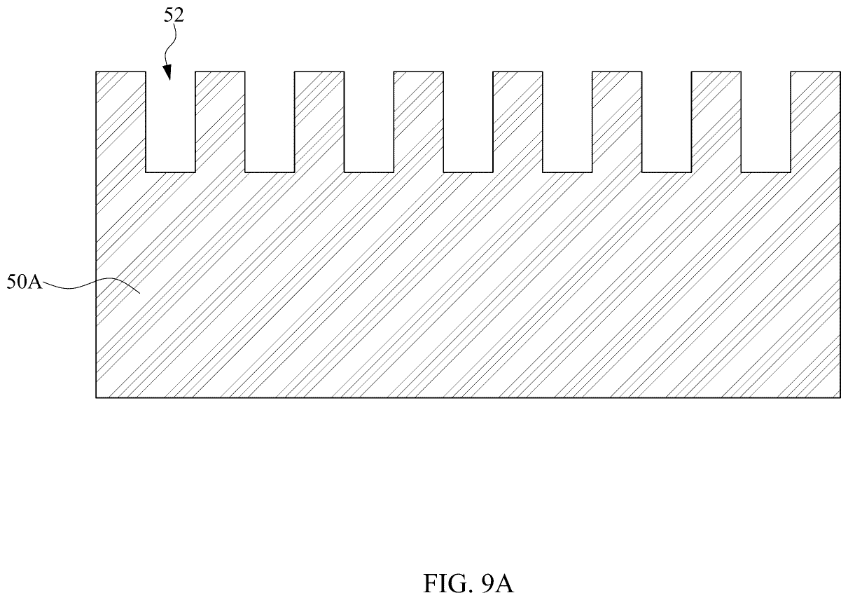

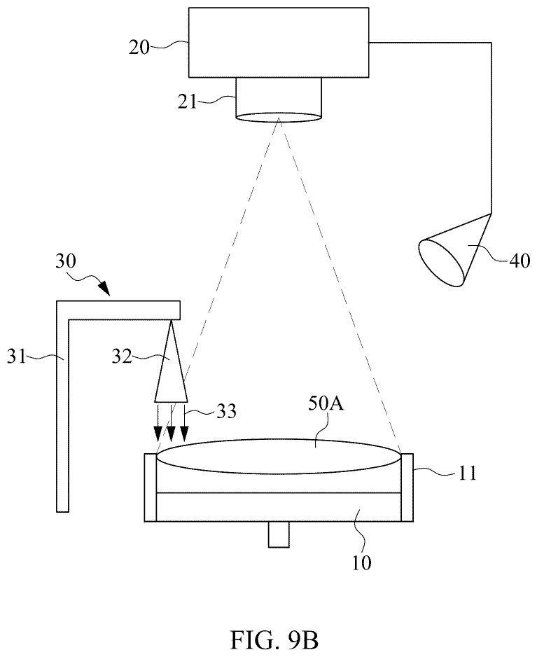

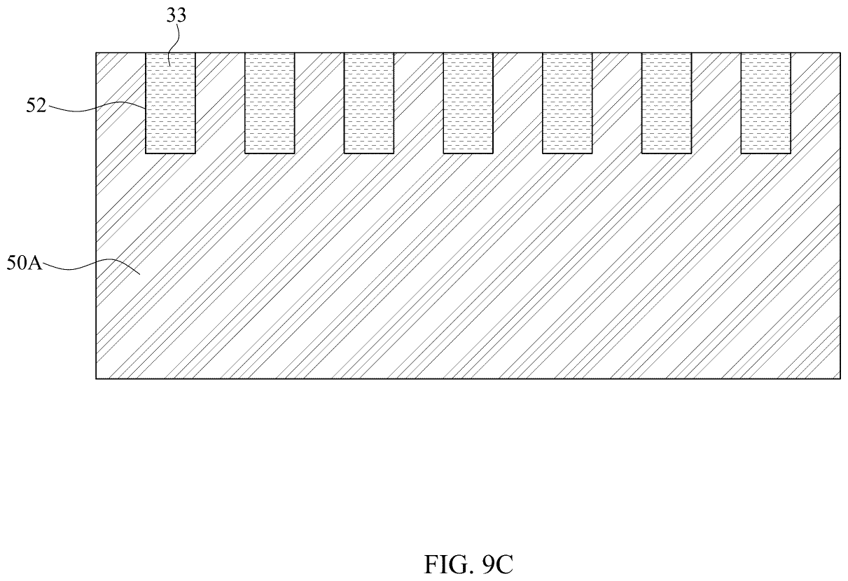

FIG. 8 is a flowchart representing a method 800 for cleaning a semiconductor device using a wet process system according to various aspects of the present disclosure. In some embodiments, the method 800 for forming the semiconductor device includes a number of operations (801, 802, and 803). The method 800 for cleaning the semiconductor device will be further described according to one or more embodiments. It should be noted that the operations of the method 800 may be rearranged or otherwise modified within the scope of the various aspects. It should further be noted that additional processes may be provided before, during, and after the method 800, and that some other processes may be only briefly described herein. FIGS. 9A to 9C are diagrammatic perspective views illustrating various stages in the method 800 for forming the semiconductor device according to aspects of one or more embodiments of the present disclosure.

With reference to FIG. 9A, the method 800 begins at operation 801 where a wafer 50A with semiconductor structures to be cleaned through a wet cleaning process is provided. The semiconductor structures are formed on a front surface (i.e., the major surface) of the wafer 50A. For example, in some embodiments, the semiconductor device may be a fin field effect transistor (FinFET) device comprising a plurality of fin structures. During the formation of the fin structures, trench portions 52A can be formed and may be cleaned before further processing. In some embodiments, inter-layer dielectric (ILD)/inter-metal dielectric layers (IMDs) may be patterned using photolithography techniques to form trench portions and vias. The trench portions 52A may be cleaned before further processing.

The method 800 continues with operation 802 in which the wafer 50A is cleaned through the wet process system, in accordance with some embodiments as shown in FIG. 9B. The wafer 50A is held by a wafer holder 10 and fixed by clamp pins 11 and can spin or not spin according to demand. The liquid provider 30 provides a cleaning liquid 33 onto the major surface of the wafer 50A. The wafer 50A receives thermal energy from an emitter 21 of a thermal-emitting apparatus 20. In some embodiments, the wafer 50A may spin so as to help the cleaning liquid 33 overcome surface tension, so the cleaning liquid 33 can easily flow into the trench portions 52A as shown in FIG. 9C and thus cleaning efficiency can be increased.

Operation 903 is conducting further processing to complete formation of the semiconductor device.

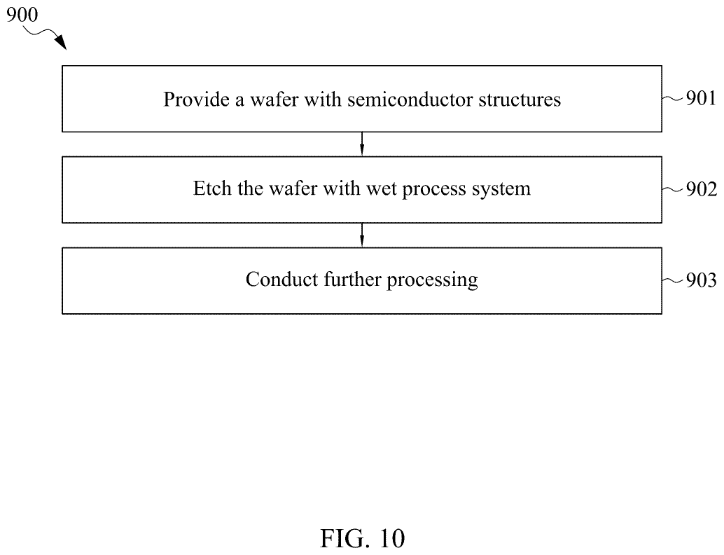

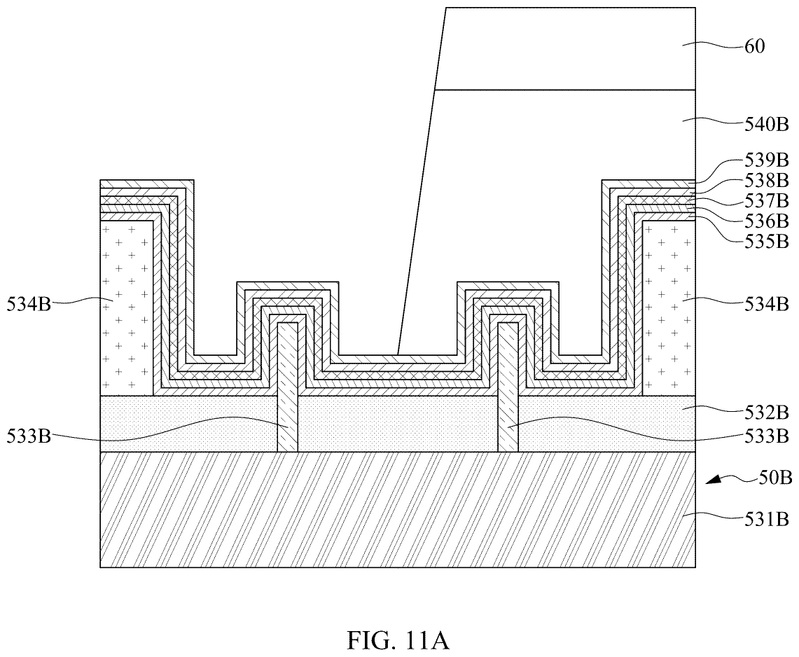

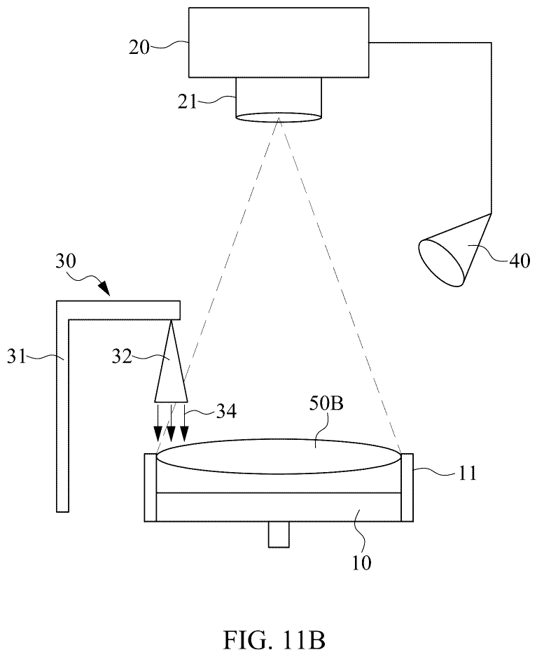

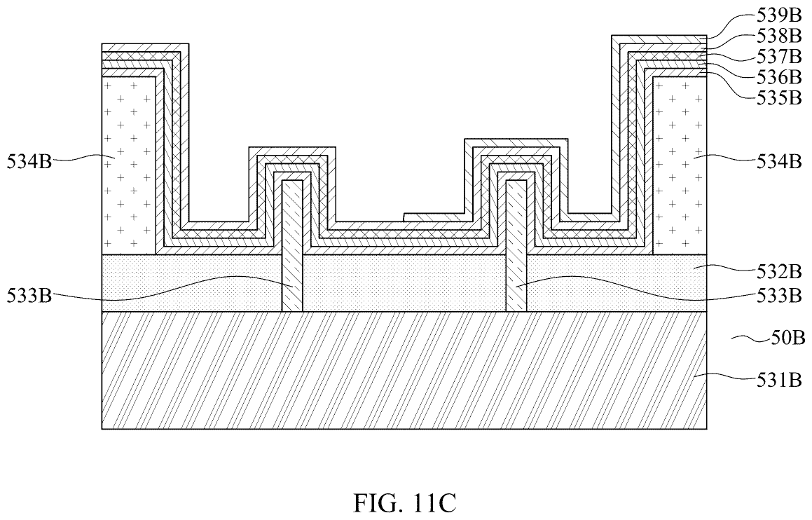

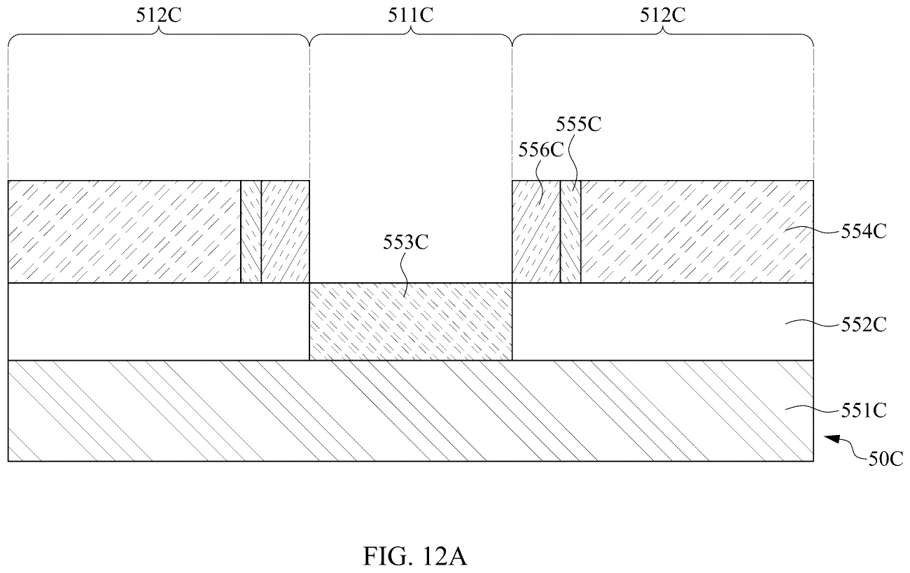

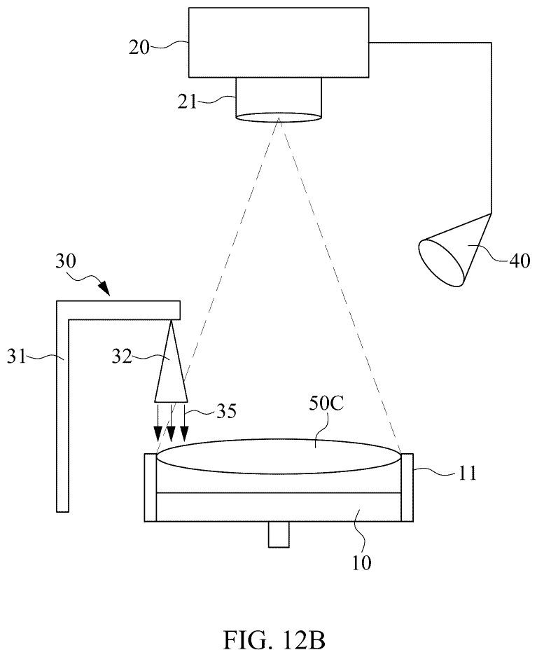

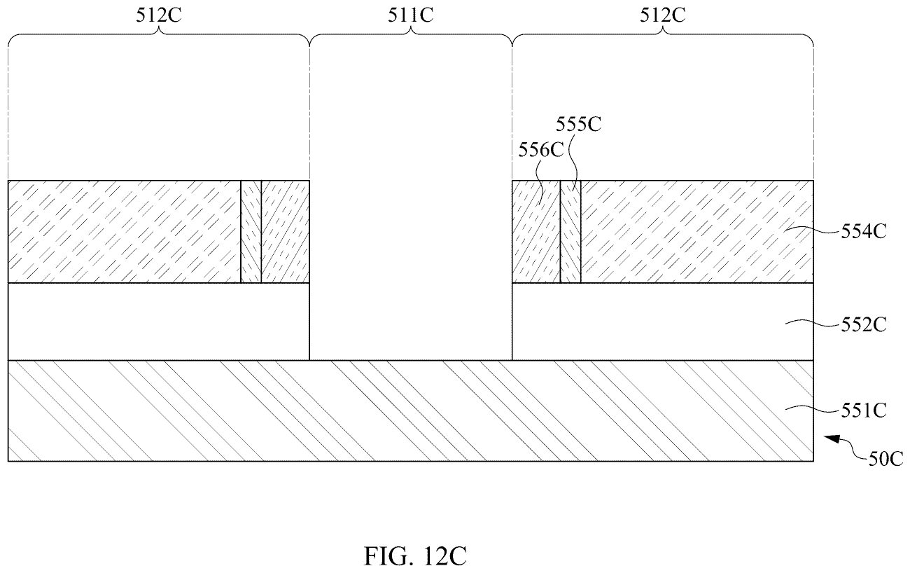

FIG. 10 is a flowchart representing a method 900 for etching a semiconductor device using a wet process system according to various aspects of the present disclosure. In some embodiments, the method 900 for etching the semiconductor device includes a number of operations (901, 902, and 903). The method 900 for etching the semiconductor device will be further described according to one or more embodiments. It should be noted that the operations of the method 900 may be rearranged or otherwise modified within the scope of the various aspects. It should further be noted that additional processes may be provided before, during, and after the method 900, and that some other processes may be only briefly described herein. FIGS. 11A to 11C and FIG. 12A to 12C are diagrammatic perspective views illustrating various stages in the method 900 for etching the semiconductor device according to aspects of one or more embodiments of the present disclosure.

In some embodiments, the method 900 begins at operation 901 where a wafer 50B with semiconductor structures to be etched through a wet etching process is provided as shown in FIG. 11A. The wafer 50B has semiconductor structures formed on a front surface (i.e., the major surface) of the wafer 50B. The wafer 50B comprises a substrate 531B overlaid with an epitaxy layer 532B, channel structures 533B formed on the substrate 531B, interlayer dielectric (ILD) structures 534B, multiple overlying layers 535B-539B and a bottom anti-reflective coating (BARC) 540B. Bottom portions of the channel structures 533B are surrounded in the epitaxy layer 532B, while upper portions of the channel structures 533B are exposed though the epitaxy layer 532B. The ILD structures 534B are formed on the epitaxy layer 532B and separated from the epitaxy layer 532B through the overlying layers 535B-539B. The overlying layers 535B-539B are formed over an upper surface of the epitaxy layer 532B, surround the upper portions of the channel structures 533B and surround the ILD structures 534B. In some embodiments, the overlying layers 535B-539B may comprise a spacer layer 535B, a high-k layer 536B, a titanium silicon nitride (TSN) 537B, a tantalum nitride (TaN) layer 538B, a titanium nitride (TiN) layer 539B, but the disclosure is not limited thereto. The BARC 540B is formed on a partial portion of the titanium nitride (TiN) layer 539B and is patterned using a photoresist 60. The BARC 540B can be made of nitrogen-free material, such as silicon rich oxide, or silicon oxycarbide (SiOC), but the disclosure is not limited thereto.

The method 900 continues with operation 902 in which the wafer 50B is etched through the wet process system, in accordance with some embodiments as shown in FIG. 11B. The wafer 50B is held by a wafer holder 10 and fixed by clamp pins 11 and can spin or not spin according to demand. The liquid provider 30 provides an etching liquid 34 onto the major surface of the wafer 50B. The wafer 50B receives thermal energy from an emitter 21 of a thermal-emitting apparatus 20. The TiN layer 539B exposed from the BARC 540B can be removed while the TiN layer 539B covered by the BARC 540B still retains on the wafer 54B. After removing the BARC 540B and the photoresist 60, the TaN layer 538B partially retains on the wafer 54B.

Operation 903 is conducting further processing to complete formation of the semiconductor device.

In some embodiments, the method 900 begins at operation 901 where a wafer 50C with semiconductor structures to be etched through a wet etching process is provided as shown in FIG. 12A. The wafer 50C comprises a substrate 551C, a cap layer 552C, a semiconductor structure 553C, a first dielectric layer 554C, a second dielectric layer 555C and a third dielectric layer 556C. In some embodiments, the semiconductor structure 553C may be a polysilicon structure. The first dielectric layer 554C, the second dielectric layer 555C and the third dielectric layer 556C may include materials different from each other. In some embodiments, the first dielectric layer 554C may be an interlayer dielectric (ILD) structures 554C that includes silicon oxide, the second dielectric layer 555C may include a silicon nitride (SiN) layer 555C, and the third dielectric layer 556C may include a silicon oxycarbide (SiOCN) layer 556C, but the disclosure is not limited thereto. The cap layer 552C is formed on the substrate 551C. The semiconductor structure 553C is formed on the substrate 551C and surrounded by the cap layer 552C to expose an upper surface of the semiconductor structure 553C. The ILD structures 554C, the SiN layer 555C and the SiOCN layer 556C are formed on the cap layer 552C. The SiN layer 555C is formed between the ILD structures 554C and the SiOCN layer 556C.

The wafer 50C has predetermined regions including treating areas 511C corresponding to the semiconductor structure 553C and protecting areas 512C corresponding to the ILD structures 554C, the SiN layer 555C and the SiOCN layer 556C formed on the cap layer 552C.

The method 900 continues with operation 902 in which the wafer 50C is etched through the wet process system, in accordance with some embodiments as shown in FIG. 12B. The wafer 50C is held by a wafer holder 10 and fixed by clamp pins 11 and can spin or not spin according to demand. The liquid provider 30 provides an etching liquid 35 onto the major surface of the wafer 50C. The wafer 50C receives thermal energy from an emitter 21 of a thermal-emitting apparatus 20 through a patterned screen 211/a detachable patterned screen 212 as shown in FIGS. 4B and 5B. The patterned screen 211/the detachable patterned screen 212 include emitting portions 211a, 212a corresponding to the treating area 511C on the wafer 50C and blocking portions 211b corresponding to the protecting areas 512C on the wafer 50C. Through the patterned screen 211/the detachable patterned screen 212 of the emitter 21, only the etching liquid 35 provided onto the treating areas 511C can be heated, so that exposed semiconductor structure 553C can be removed while the ILD structures 554C, the SiN layer 555C and the SiOCN layer 556C are retained as shown in FIG. 12C. Therefore, selective etching can be achieved by using the patterned screen 211/the detachable patterned screen 212 of the emitter 21.

Operation 903 is conducting further processing to complete formation of the semiconductor device.

In the wet process system in accordance with the present disclosure, the patterned screen 211/detachable patterned screen 212 of the emitter 21 can increase temperature of etching/cleaning liquid on specific areas on wafers to be etched or cleaned. Higher temperature would boost removal ability, such as wetting/strip rate, etching/cleaning efficiency and so on even though the wafers to be etched/cleaned have decreased process window.

In some embodiments, a wet process system comprises a wafer holder configured to hold a wafer; a thermal-emitting apparatus located above the wafer holder along a Y axis and configure to emit thermal radiation to the wafer; and a liquid provider configured to provide a treating liquid onto the wafer, wherein the treating liquid provided on the wafer is heated by the thermal radiation emitted from the thermal-emitting apparatus.

In some embodiments, a wet process system comprises a wafer holder configured to hold a wafer comprising a spin base; a thermal-emitting apparatus located above the wafer holder along a Y axis and comprising: an emitter configure to emit thermal radiation to the wafer; and a rotational chuck attached to the emitter; and a liquid provider configured to provide a treating liquid onto the wafer, wherein the emitter driven by the rotational chuck spins along with spinning of the wafer holder driven by the spin base; and wherein the treating liquid provided on the wafer is heated by the thermal radiation emitted from the emitter.

In some embodiments, a process for etching or cleaning a semiconductor device comprises providing a wafer with semiconductor structures; holding the wafer by a wafer holder so that the semiconductor structures face a thermal-emitting apparatus; providing a treating liquid flowing out from a liquid provider onto the semiconductor structures on the wafer; and transmitting thermal radiation toward the semiconductor structures on the wafer from the thermal-emitting apparatus located above the wafer holder along a Y axis, wherein a temperature difference between the treating liquid before receiving the thermal radiation and the treating liquid after receiving the thermal radiation ranges from about 0.1° C. to about 100° C.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A wet process system, comprising:
a wafer holder configured to hold a wafer;
a thermal-emitting apparatus located above the wafer holder along a Y axis and configure to emit thermal radiation to the wafer; and
a liquid provider configured to provide a treating liquid onto the wafer,
wherein the treating liquid provided on the wafer is heated by the thermal radiation emitted from the thermal-emitting apparatus.

2. The wet process system of claim 1, wherein the thermal-emitting apparatus emits the thermal radiation with a pattern, so that the treating liquid on the wafer is partially heated by the thermal radiation.

3. The wet process system of claim 1, wherein the thermal-emitting apparatus has an emitter with a patterned screen comprising:
at least one emitting portion allowing the thermal radiation to pass toward the wafer; and
at least one blocking portion blocking the thermal radiation from being transmitted toward the wafer.

4. The wet process system of claim 1, wherein the thermal-emitting apparatus has an emitter with a detachable patterned screen comprising:
at least one emitting portion allowing the thermal radiation to pass toward the wafer; and
at least one blocking portion blocking the thermal radiation from being transmitted toward the wafer.

5. The wet process system of claim 1, wherein a distance between the thermal-emitting apparatus and the wafer holder ranges from about 1 cm to about 100 cm.

6. The wet process system of claim 1, wherein the thermal radiation is generated by a light emitted from the thermal-emitting apparatus, and wavelength of the light ranges from about 300 nm to about 3,000 nm.

7. The wet process system of claim 1, wherein the thermal radiation is generated by a light emitted from the thermal-emitting apparatus, and power of the light ranges from about 0.1 W to 2,000 W.

8. A wet process system, comprising:
a wafer holder configured to hold a wafer comprising a spin base;
a thermal-emitting apparatus located above the wafer holder along a Y axis and comprising:
an emitter configure to emit thermal radiation to the wafer; and
a rotational chuck attached to the emitter; and
a liquid provider configured to provide a treating liquid onto the wafer,
wherein the emitter driven by the rotational chuck spins along with spinning of the wafer holder driven by the spin base; and
wherein the treating liquid provided on the wafer is heated by the thermal radiation emitted from the emitter.

9. The wet process system of claim 8, wherein
the wafer holder spins the wafer at a spin speed ranging from about 1 rpm to about 1,000 rpm; and
the emitter driven by the rotational chuck spins at a spin speed ranging from about 1 rpm to about 1,000 rpm.

10. The wet process system of claim 8, wherein the wafer holder spins the wafer at a spin speed, which is substantially identical to a spin speed of the emitter driven by the rotational chuck.

11. The wet process system of claim 8, wherein the emitter has a patterned screen comprising:
at least one emitting portion allowing the thermal radiation to pass toward the wafer; and
at least one blocking portion blocking the thermal radiation.

12. The wet process system of claim 8, wherein the thermal-emitting apparatus has an emitter with a detachable patterned screen comprising:
at least one emitting portion allowing the thermal radiation to pass toward the wafer; and
at least one blocking portion blocking the thermal radiation.

13. The wet process system of claim 8, wherein a field of view (FOV) from a center of the emitter to an edge of the wafer ranges from about 15° to about 175°.

14. The wet process system of claim 8, further comprising a real-time temperature sensor configured to monitor a temperature of the treating liquid on the wafer and to transmit collected temperature data to the thermal-emitting apparatus.

15. The wet process system of claim 8, further comprising a speed sensor, which monitors a spin speed of the wafer and transmits collected speed data to the wafer holder, the thermal emitting apparatus or both, so that the spinning of the wafer holder, spinning of the emitter or both are real-time controlled.

16. A process for etching or cleaning a semiconductor device, comprising:
providing a wafer with semiconductor structures;
holding the wafer by a wafer holder so that the semiconductor structures face a thermal-emitting apparatus;
providing a treating liquid flowing out from a liquid provider onto the semiconductor structures on the wafer; and
transmitting thermal radiation toward the semiconductor structures on the wafer from the thermal-emitting apparatus located above the wafer holder along a Y axis,
wherein a temperature difference between the treating liquid before receiving the thermal radiation and the treating liquid after receiving the thermal radiation ranges from about 0.1° C. to about 100° C.

17. The process of claim 16, wherein
the semiconductor structures on the wafer have a predetermined pattern including treating areas radiated by the thermal radiation; and protecting areas not radiated by the thermal radiation; and
the thermal-emitting apparatus has an emitter with a patterned screen comprising:
emitting portions correspond to the treating areas and allow the thermal radiation to pass toward the treating areas; and
blocking portions correspond to the protecting areas and block the thermal radiation from being transmitted toward the wafer.

18. The process of claim 16, wherein
the semiconductor structures on the wafer have a predetermined pattern including treating areas radiated by the thermal radiation; and protecting areas not radiated by the thermal radiation; and
the thermal-emitting apparatus has an emitter with a detachable patterned screen comprising:
emitting portions correspond to the treating areas and allow the thermal radiation to pass toward the treating areas; and
blocking portions correspond to the protecting areas and block the thermal radiation from being transmitted toward the wafer.

19. The process of claim 16, wherein the thermal-emitting apparatus comprises an emitter, and the emitter spins along with spinning of the wafer, and wherein a spin speed of the wafer is substantially identical to a spin speed of the emitter.

20. The process of claim 16, wherein the treating liquid is provided onto the wafer to form a thin film with a thickness ranging from about 0.01 μm to about 3 mm.
